(19) United States
(12) Patent Application Publication
(10) Pub. No.: US 2013/0177760 A1
(43) Pub. Date: Jul. 11, 2013

(54) MIXED METAL OXIDE BARRIER FILMS AND ATOMIC LAYER DEPOSITION METHOD FOR MAKING MIXED METAL OXIDE BARRIER FILMS

(71) Applicant: Eric R. Dickey, Portland, OR (US)

(72) Inventor: Eric R. Dickey, Portland, OR (US)

(73) Assignee: Lotus Applied Technology, LLC, Hillsboro, OR (US)

(21) Appl. No.: 13/546,930

(22) Filed: Jul. 11, 2012

Related U.S. Application Data
(60) Provisional application No. 61/506,607, filed on Jul. 11, 2011.

(51) Int. Cl. C23C 16/40

(52) U.S. Cl. CPC C23C 16/40
USPC 428/336; 427/535

(57) ABSTRACT

A method of forming a thin barrier layer film of a mixed metal oxide, such as a mixture of aluminum, titanium, and oxygen (AlTiO), comprises sequential exposure of a substrate having a surface temperature less than 100° C. to a halide precursor, an oxygen plasma, and a metalorganic precursor. Barrier films formed by the method exhibit improved water vapor transmission rate (WVTR) over single metal oxide films and nanolaminates of two metal oxides having a similar overall thickness.

### RELATED APPLICATION

This application claims the benefit under 35 U.S.C. §119(e) from U.S. Provisional Patent Application No. 61/506,607, filed Jul. 11, 2011, which is hereby incorporated by reference in its entirety.

### TECHNICAL FIELD

The field of the present disclosure relates to mixed metal oxide barrier films and processes for deposition of such barrier films.

### BACKGROUND

Gases, liquids, and other environmental factors may cause deterioration of various goods, such as food, medical devices, pharmaceutical products, and electrical devices. Thus, conventionally, barrier layers have been included on or within the packaging associated with the sensitive goods to prevent or limit the permeation of gases or liquids, such as oxygen and water, through the packaging during manufacturing, storage, or use of the goods.

Atomic layer deposition (ALD) is a thin film deposition process described in U.S. Patent Application Publication No. US 2007/0224348 A1 of Dickey et al. (“the '348 publication”), filed Mar. 26, 2007 as U.S. application Ser. No. 11/691,421 and entitled Atomic Layer Deposition System and Method for Coating Flexible Substrates, and in US 2010/0189900 A1 of Dickey et al. (“the '900 publication”), filed Apr. 6, 2010 as U.S. application Ser. No. 12/755,239 and entitled Atomic Layer Deposition System And Method Utilizing Multiple Precursor Zones for Coating Flexible Substrates, both of which are hereby incorporated by reference. Thin film deposition in accordance with the methods and systems disclosed in the '348 and '900 publications have been proposed for deposition of barrier layers on flexible substrates for packaging for sensitive goods and other uses.

Complex multilayer barrier layers including five or six pairs of alternating organic and inorganic layers have been used to prevent the permeation of oxygen and water through plastic substrates of organic light emitting diodes (OLEDs). Some such barriers are so-called nanolaminates made by ALD, having individual layer thicknesses under 10 nanometers (nm). However, multilayer barriers result in a relatively high overall barrier thickness that is not ideal for thin film flexible packaging. Additionally, although some such barriers may exhibit a good short-term water vapor transmission rate (WVTR), many known multilayer barriers have been found to simply have long lag times for vapor transmission rather than significantly reducing steady state permeability.

Aluminum oxide (Al₂O₃, also known as alumina) is a material which decomposes when exposed to high humidity/high temperature environments, making it a risky choice as a moisture barrier film. It also suffers from the lag time problem mentioned above, even for single sided coatings, making quality verification difficult and raising concerns about long term performance for thick Al₂O₃ coatings in high humidity environments. On the other hand, the present inventor has recognized that titanium dioxide (TiO₂, also known as titania) formed using an oxygen-containing plasma makes an excellent water vapor barrier, as disclosed in U.S. patent application Ser. No. 12/632,749, filed Dec. 7, 2009 and published as US 2010/014371 0 A1 (“the '710 publication”), which is hereby incorporated by reference. TiO₂ is stable in high humidity environments, and has no single-sided lag time issue. However, the present inventor has found that TiO₂ has a high refractive index, which can lead to optical transmission loss due to reflection, particularly as the required TiO₂ film thickness increases.

Conventional wisdom holds that nanolaminates make better barrier films than mixed materials. See, for example, U.S. Pat. No. 4,486,487 disclosing aluminum-titanium-oxide nanolaminates with Al₂O₃ and TiO₂ layers. And many researchers are investigating nanolaminates as a way to improve barrier performance.

A need remains for barrier films having very low steady-state vapor permeability and improved optical transmission.

### BRIEF DESCRIPTION OF THE DRAWINGS

FIG. 1 is a graph illustrating WVTR as a function of film thickness for mixed AlTiO films according to Example 1 discussed below, and comparing to TiO₂ films prepared under similar deposition conditions;

FIG. 2 compares WVTR for the same mixed and TiO₂ films as a function of the number of deposition cycles;

FIG. 3 is a schematic cross-section illustration of a substrate with a single mixed AlTiO film deposited thereon;

FIG. 4 is a schematic cross-section illustration of a substrate with mixed AlTiO films deposited on both sides; and

FIG. 5 is a schematic cross-section view illustrating a system for thin film deposition on a flexible web configured in a band loop.

### DETAILED DESCRIPTION OF PREFERRED EMBODIMENTS

In accordance with the present disclosure, a barrier film comprises a mixture of different metal oxides deposited on a substrate. In contrast to many prior methods of forming multi-layer barriers, mixtures according to the present disclosure may have no detectably distinct layers (i.e., essentially a homogenous mixture), or may have alternating layers of different metal oxides that are each less than approximately 1.5 nm thick or, more preferably, less than approximately 1.0 nm thick, or even more preferably less than approximately 0.5 nm thick, or in some cases less than approximately 0.3 nm thick. In some embodiments, mixed films are formed by no more than 15 consecutive deposition cycles of a first metal oxide material before switching to the second metal oxide. In other embodiments, no more than about 2 or 3 molecular layers of a first metal oxide are formed until approximately 10 angstroms (Å) (approximately 1 nm) of the first metal oxide material is deposited, before switching to and depositing a second metal oxide material to a similar thickness, and so on until the desired total thickness of the mixed oxide film is achieved. Such mixtures may consist of tens, hundreds, or thousands of such alternating molecular layers of multiple metal oxides, depending on the desired thickness.

Mixtures according to preferred embodiments may be formed by ALD using precursors from different chemical families for the two metals, and oxygen radicals, such as an oxygen-containing plasma, as the oxygen source. More specifically, in various embodiments, one metal precursor is from a halide family (e.g., chloride or bromide), and another is from a metalorganic family (e.g., alkyl). For example, in one embodiment a mixture of titania and alumina (hereinafter an AlTiO) is deposited by ALD using a halide such as titanium tetrachloride (TiCl₄) as the titanium precursor, an alkyl such as trimethylaluminum (TMA) as the aluminum precursor, and a DC plasma formed of dry air as the oxygen precursor for both metal oxides. The oxygen radical-containing plasma preferably contacts the substrate directly (a direct plasma). Mixed AlTiO films formed according to the present disclosure have been observed to have a stable WVTR performance for a given film thickness that is far superior to what is observed for either TiO₂ or Al₂O₃ alone, or for so-called “nanolaminates” of the two materials having individual layer thicknesses exceeding 1.5 nm, as illustrated by the examples below. Mixed AITiO films may also have a refractive index that is significantly lower than TiO₂ alone. In some embodiments, such mixed AlTiO barrier films have an overall thickness in the range of approximately 2 nm to 10 nm.

Mixed metal oxide films made by ALD using oxygen plasma have been found to exhibit properties that are superior to multi-layer or mixed films made by conventional thermal ALD processes, such as when water is used as the oxygen precursor and the reactor and substrate temperature are heated to 100° C. or greater during deposition. For example, in one thermal ALD experiment, a mixed AlTiO film having a 1:1 mixture ratio of alumina to titania (mole ratio) was deposited in a Planar Systems P400 batch reactor at 100° C. substrate temperature by alternating ALD cycles of the two metal oxides 40 times—i.e., by (a) exposing the substrate to TiCl₄ precursor, (b) exposing it to water vapor, (c) exposing it to TMA, (d) exposing it to water vapor, and repeating steps (a)-(d) forty times. This process is represented by the formulaic notation: 40*(1*TiO₂+1*Al₂O₃). Such a 40-cycle mixed TiO₂/Al₂O₃ film made by thermal ALD had an overall thickness of 6.2 nm and exhibited poor (high) WVTR of approximately 0.5 g/m²/day. This is worse than either TiO₂ or Al₂O₃ films alone when made to the same thickness by thermal ALD processing at the same temperature, and also much worse than either individual material, or mixed material produced in an equivalent run using a plasma-based process.

Also, some attempts to form barriers of nanolaminate stacks of TiO₂ and Al₂O₃ using oxygen-containing plasma have not yielded good results. For example, attempts to make simple film stacks such as (5 nm TiO₂+5 nm Al₂O₃+5 nm TiO₂), or (2 nm TiO₂+2 nm Al₂O₃+2 nm TiO₂) resulted in films that behaved essentially like an average of the TiO₂ and Al₂O₃ materials, with WVTR generally in between the performance of the two materials, or in some cases worse than either material.

In comparison, films comprising an AlTiO mixture made using oxygen-containing plasma at less than 100° C. exhibit:
1) Stable long term barrier performance in WVTR (unlike Al₂O₃ alone);
2) A refractive index of less than approximately 2.0 (and typically in the range of approximately 1.8 to 1.9), which may result in negligible or minimum reflective loss on flexible polymer films such as PET, BOPP and acrylics for coatings up to 10 to 20 nm (and significantly better than pure TiO₂); and
3) A 30% to 70% reduction in required thickness (and therefore required number of cycles) compared with either Al₂O₃ or TiO₂ alone, or for nanolaminates of those materials with individual layers significantly greater than 1 nm, for a given WVTR performance.
   In addition to reducing the number of deposition cycles required to achieve good WVTR and improved optical qualities, thinner films are more flexible and less susceptible to damage upon bending of coated flexible substrates.

Embodiments of a film comprising an AlTiO mixture made using an oxygen-containing plasma may exhibit WVTR less than 5×10⁻⁴ g/m²/day at a thickness of less than about 6 or 8 nm, for example films having a thickness of about 4 or 5 nm. Other embodiments of mixed AlTiO films having a thickness of less than approximately 3 or 4 nm may exhibit WVTR of less than 0.005 g/m²/day. Although current test instruments are not sensitive enough to verify it, the present inventors expect that mixed AlTiO films having a thickness of less than approximately 8 or 10 nm will have a WVTR of less than 5×10⁻⁶ g/m²/day.

For purposes of the present disclosure and claims, WVTR is determined in accordance with ASTM F1249-06(2011) “Standard Test Method for Water Vapor Transmission Rate Through Plastic Film and Sheeting Using a Modulated Infrared Sensor” at 38° C. (+/−0.1° C.) and 90% RH, but with a test instrument configured with a coulometric sensor including electrodes coated with phosphorous pentoxide (P₂O₅) rather than a modulated infra-red sensor. In the experimental results set forth below, the WVTR measurements were made either using a MOCON Aquatran® WVTR measurement instrument (indicated as Instrument “MOC”) or an Illinois Instruments Model 7001 WVTR test system (indicated as Instrument “II”). Both the MOCON Aquatran and Illinois Instruments 7001 test systems implement ASTM F1249 with a coulometric sensor including electrodes coated with P₂O₅ for improved sensitivity over an infra-red sensor. The MOCON Aquatran instrument has a reliable lower measurement limit of approximately 5×10⁻⁴ g/m²/day, whereas test instruments implementing an infra-red sensor typically have a lower limit of approximately 5×10⁻² g/m²/day. Other available test method specifications include DIN EN ISO 15106-3 (2005). It is possible that over time improved test methods, sensors, and instruments will be developed or discovered to provide improved sensitivity, with lower limits down to 5×10⁻⁶ g/m²/day or lower, and improved accuracy; and that recognized standards will be adopted for such improved test methods. To the extent that future test methods, sensors, instruments, and standards provide improvements in sensitivity and accuracy over the test methods used to gather WVTR data disclosed herein, they may be used to determine WVTR under the claims.

Mixed films according to the present disclosure can be made by the roll-to-roll deposition system disclosed in the '348 publication, using a halide such as TiCl₄ in a first precursor zone, a metalorganic such as TMA in a second precursor zone, and placing an oxygen radical generator in the isolation zone (for example a direct DC plasma generator). In one embodiment, a DC plasma generator is used to energize an oxygen-containing gas (for example dry air, oxygen gas (O₂), carbon dioxide(CO₂), or mixtures of two or more of the foregoing, with or without added nitrogen (N₂) carrier gas) flowing through the isolation zone at a pressure slightly higher than the first and second precursor zones. In another embodiment, a stacked reactor configuration may utilize a multi-zone stack, such as the 5-zone stack illustrated in FIG. 5 of the '900 publication, wherein a halide such as TiCl₄ is introduced in the top and bottom precursor zones and a metalorganic such as TMA is introduced in middle precursor zone, or vice versa, and oxygen radicals are generated from oxygen-containing gas introduced in the intermediate isolation zones separating the TiCl₄ and TMA zones.

The deposition process, including growth rate and barrier properties, are relatively insensitive to substrate temperature, at least in the range of about 50° C. to 100° C., which facilitates the use of flexible polymer film substrates such as bi-axially oriented polypropylene (BOPP), which cannot withstand temperatures greater than about 70° C.

It is expected that mixed metal oxide films in accordance with the present disclosure will have barrier properties (WVTR, oxygen transmission, etc.) that are more stable than Al₂O₃ and many other single metal oxide barriers. For example, upon exposure to test conditions of 38° C. and 90% RH for a time period in the range of 24 hours, 48 hours, or up to one week, mixed AlTiO films deposited on a flexible polymer substrate are expected to exhibit an increase (or change) in WVTR of less than 50% over initial settled readings. In another prophetic example, upon exposure to test conditions of 38° C. and 90% RH for a time period in the range of two weeks and 30 days, mixed AlTiO barrier films deposited on a flexible polymer substrate are expected to exhibit an increase in WVTR of less than 100% over initial settled readings.

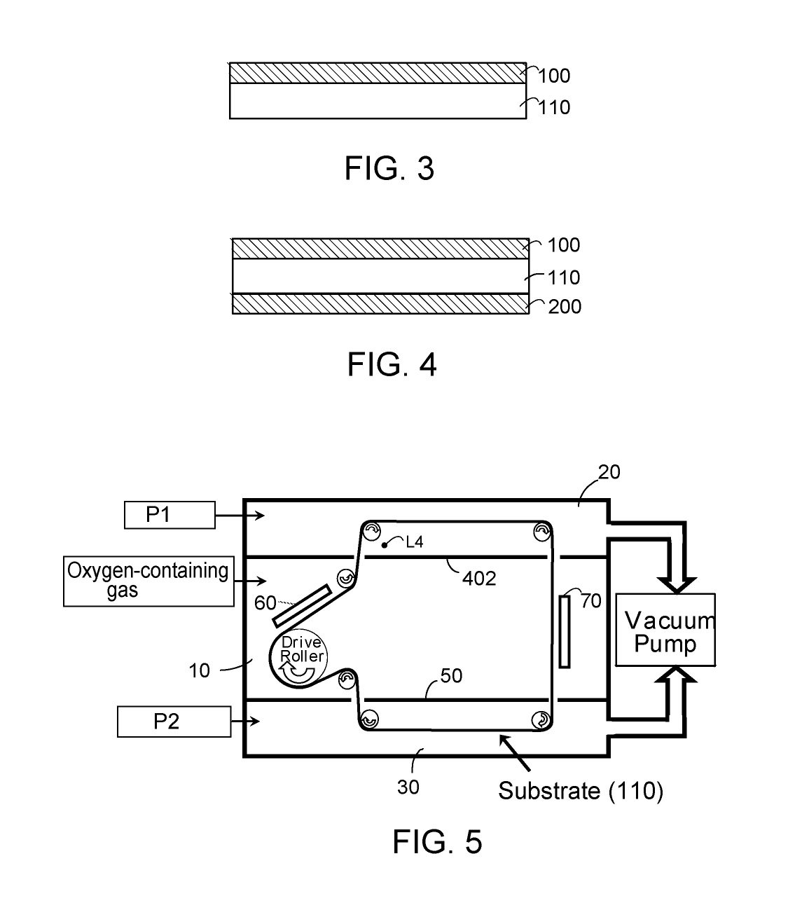

FIG. 3 illustrates a cross section of a single thin film barrier layer of mixed AlTiO 100 deposited on a flexible substrate 110 (also referred to as a single-sided barrier layer). FIG. 4 illustrates a cross section of first and second thin film barrier layers 100 and 200 of mixed AlTiO deposited on opposite sides of a flexible substrate 110 (also referred to as a double-sided barrier).

FIG. 5 provides a schematic illustration of a prototype roll-to-roll deposition system used to perform tests of Examples 1 and 4, below. This system is consistent with the systems described in the '348 publication and especially with the system of FIG. 5 of the '710 publication. With reference to FIG. 5 herein, a “loop-mode” configuration wraps a substrate 110 into an endless band (loop), which includes a single path that performs two ALD cycles on each revolution as the substrate moves from the central isolation zone 10, into the first precursor zone 20, back to the isolation zone 10, to the second precursor zone 30, and to finish back in the isolation zone 10. As the substrate web 110 travels between zones 10, 20, 30 it passes through slit valves, which are just slots in divider plates 40, 50 that separate the different zones. In this configuration the substrate web 110 can be passed repeatedly through the precursor and isolation zones (10→20→10→30) in a closed loop. (This system is referred to herein as a “roll-to-roll” deposition system, even though the loop substrate configuration used for experimental purposes does not involve transporting the substrate from a feed roll to an uptake roll.) In the loop configuration illustrated in FIG. 5, a full traverse of the loop path results in two ALD deposition cycles when two plasma generators 60, 70 are employed in isolation zone 10. The substrate band is circulated along this loop path×number of times to attain 2×ALD cycles—half of the first precursor and half of the second precursor (expressed as: x*(1*TiO₂+1*A₂O₃) herein). A modified version of the system of FIG. 5 herein was utilized to generate test samples according to Examples 2, 3, and 5, as described below, in some cases performing only a single ALD cycle on each revolution of the substrate.

### Example 1

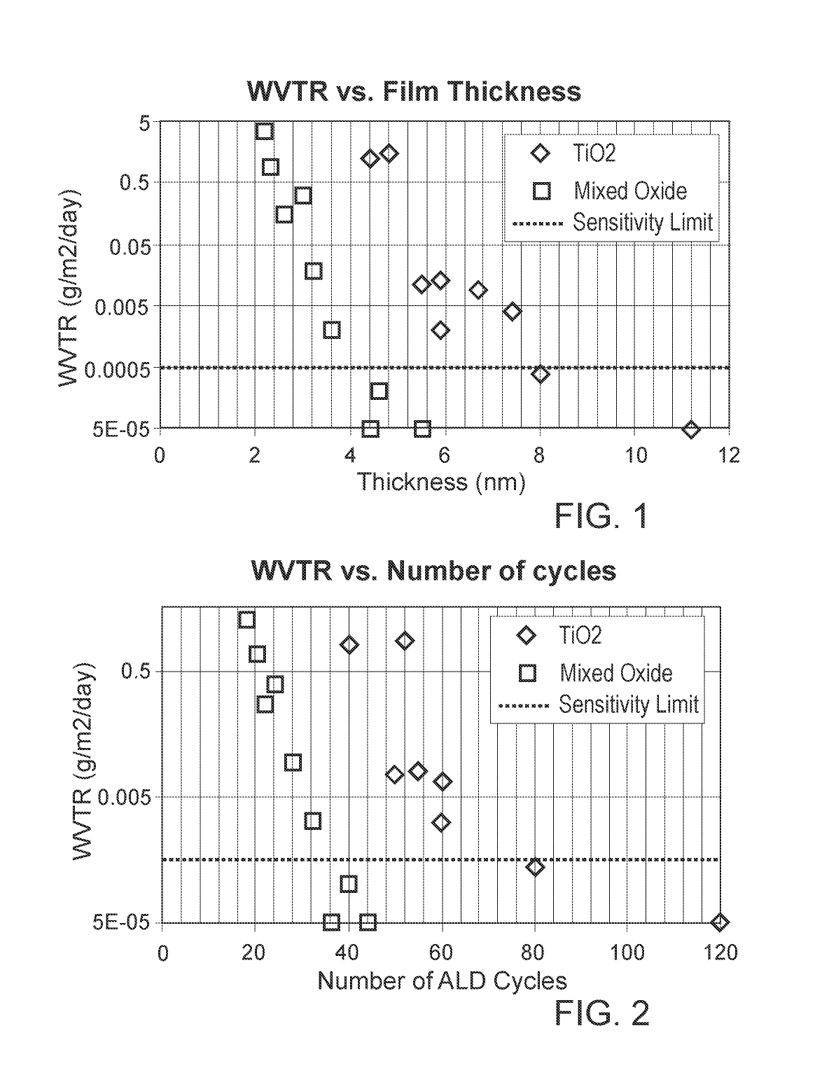

Films of varied thicknesses mixed in a 1:1 cycle ratio (x*(1*TiO₂+1*Al₂O₃)) were deposited on a substrate of DuPont Tejin Mellinex® ST-504 in experimental runs at 80° C. using a deposition system having band loop configuration according to FIG. 5, using a dry air plasma, and transporting the substrate at 30 meters/minute (m/min). At this transport speed, the substrate was exposed to TMA precursor for approximately 1 second, to the oxygen plasma for approximately 0.25 second, and to TiCl₄ precursor for approximately 1 second, and again to the oxygen plasma for approximately 0.25 second, and then the sequence repeated. The minimum film thickness showing any barrier properties was approximately 2 nm thick achieved by 9 pairs of deposition cycles, denoted as: (9*(1*TiO₂+1*Al₂O₃)). For 12 pairs (24 total cycles), yielding a total film thickness of approximately 3 nm, the WVTR was approximately 0.03 g/m²/day, which is good enough for commercial food packaging. For 20 pairs (40 total cycles), yielding approximately 5 nm total film thickness, WVTR was below the reliable detection limit of the MOCON Aquatran system (<˜5×10⁻⁴ g/m²/day). Thus, the slope of the curve of WVTR vs. thickness was very steep. In comparison, approximately 3.0 to 3.5 nm of either Al₂O₃ or TiO₂ alone is required before any barrier properties are observed, i.e., before any improvement in WVTR is observed over the WVTR of a bare uncoated substrate. TiO₂ film must have a thickness of approximately 8-10 nm or more to reliably reach the Aquatran detection limit, and Al₂O₃ film must have a thickness of greater than about 20 nm to exhibit WVTR below the Aquatran detection limit. FIG. 1 is a graph illustrating WVTR as a function of film thickness for 1:1 ratio mixed films according to this example, and for TiO₂-only films prepared under like deposition conditions. FIG. 2 compares WVTR for the same mixed AlTiO and TiO₂ films as a function of the number of deposition cycles. The experimental data used to generate the graphs of FIGS. 1 and 2 is set forth below in Tables 1 and 2, below.

TABLE 1
Mixed AlTiO

| # Cycles | Thickness | WVTR | Instrument |
|---|---|---|---|
| 18 | 2.2 | 3.3 | II |
| 20 | 2.3 | 0.90 | II |
| 22 | 2.6 | 0.15 | II |
| 24 | 3.0 | 0.30 | II |
| 28 | 3.2 | 0.018 | II |
| 32 | 3.6 | 0.002 | II |
| 36 | 4.4 | 0.00005 | MOC |
| 40 | 4.6 | 0.0002 | MOC |
| 44 | 5.5 | 0.00005 | MOC |

TABLE 2
TiO₂

| # Cycles | Thickness | WVTR | Instrument |
|---|---|---|---|
| 120 | 11.2 | 0.00005 | MOC |
| 60 | 5.9 | 0.002 | MOC |
| 80 | 8 | 0.0004 | MOC |
| 52 | 4.8 | 1.5 | II |
| 55 | 5.9 | 0.013 | II |
| 50 | 5.5 | 0.011 | II |
| 60 | 6.7 | 0.009 | II |
| 40 | 4.4 | 1.25 | II |
| 65 | 7.4 | 0.004 | II |

### Example 2

Multiple consecutive cycles of each metal were also tested, with the number of consecutive cycles being increased gradually to determine limits for loss of properties. Films made according to the following processes behaved relatively similarly, evidencing a homogenous mixture:

2*(8*TiO₂+8*Al₂O₃)

4*(4*TiO₂+4*Al₂O₃)

8*(2*TiO₂+2*Al₂O₃)

However, a film made by the process 1*(16*TiO₂+16*Al₂O₃) produced inferior results, and in this film the Al₂O₃ stability problem mentioned above was evident.

In the experiments of this Example 2, a modified configuration of the experimental reactor shown in FIG. 5 was used. In the modified configuration, precursor inlets for both TiCl₄ and TMA were plumbed to the top precursor zone 20, each with a shut-off valve, and the plasma generator was located in the bottom precursor zone 30, into which the oxygen-containing precursor was injected. An inert gas was injected into the isolation zone 10. One of the two valves was opened to introduce a first precursor for multiple revolutions of the band loop, then that valve closed and top precursor zone purged with inert gas before opening the other valve for multiple cycles using the second precursor, and the process repeated as needed.

### Example 3

Mixtures of TiO₂/Al₂O₃ having a 1:3 and 3:1 mole ratio, i.e., n*(1*TiO₂+3*Al₂O₃) and n*(3*TiO₂+1*Al₂O₃), were produced according to the valve-controlled reactor procedure described in Example 2, above, and their WVTR was tested. For films of comparable thickness, the TiO₂-rich film showed good barrier performance (low WVTR), similar to 1:1 ratio films, but the Al₂O₃-rich mixture exhibited the long term stability problem described above and an ultimate WVTR that was much higher than 1:1 ratio AlTiO films or the 3:1 ratio TiO₂-rich film.

### Example 4

The test process applied in Example 4 was essentially the same process as in Example 1, except substrate transport speed was reduced to approximately 15 meters/min (half of the speed of Example 1, resulting in precursor and plasma exposure times being roughly doubled). Other conditions include: 65° C. substrate temperature, dry air plasma at pressure of approximately 1.4 Torr, operating in “REALD” configuration described in the '710 publication with reference to FIG. 5 thereof—band loop mode with TMA in top zone, TiCl4 in bottom zone, and two plasma electrodes 60, 70 (FIG. 6) in the center isolation zone, each electrode approximately 50 cm wide by 60 cm long, total plasma power of approximately 140 W DC distributed between the two electrodes.

At the reduced transport speed of 15 m/min, the growth rate for a single pair of cycles (1*TiO₂+1*Al₂O₃) increased to approximately 0.3 to 0.33 nm per pair, indicating that underdosing was occurring at 30 m/min. Surface saturation was achieved at around 15 m/min, and the growth rate was not observed to increase at speeds below 15 m/min. Interestingly, the thin film growth rate at a substrate speed of 15 m/min is higher than expected from average of steady state deposition of Al₂O₃ or TiO₂ films (0.16 nm for Al2O3 and 0.10 nm for TiO2—for a total of 0.26 nm per pair). The critical required thickness for onset of any barrier properties does not change, remaining at about 2 nm. However, perhaps partly because growth rate per cycle is increased, WVTR of less than 5×10⁻⁴ g/m²/day can be achieved for cycle counts as low as 2*15 pairs, or 30 total cycles, as compared with 2*18 pairs (36 total cycles) under the conditions of Example 1.

### Example 5

In another test, mixed AlTiO films were deposited in a three-step process, whereby the substrate was exposed to dry air plasma only after one of the two metal precursors (e.g., TMA→plasma→TiCl₄→TMA→plasma→TiCl₄—etc.). In other words, one of the plasma generators 60, 70 of the band loop system of FIG. 6 was deactivated. Surprisingly, films deposited by such a 3-step process did not just behave like those made by a process for forming only one of the two metal oxide films (e.g. Al₂O₃ alone). Data concerning these 3-step processes is set forth in Tables 3A and 3B below:

TABLES 3A and 3B
3-step: TiCl4 + Plasma + TMA

| Run# | #Pairs | Thickness | WVTR | Inst |
|---|---|---|---|---|
| 633 | 18 | 39 | 0.027 | II |

3-step: TMA + Plasma + TiCl4

| Run# | #Pairs | Thickness | WVTR | Inst |
|---|---|---|---|---|
| 634 | 18 | 43 | 0.004 | II |

Notably, the growth rate for each the above 3-step sequences was greater than for either of TiO₂ or Al₂O₃ alone, suggesting TMA and TiCl₄ may be reacting directly, and indicating unique chemistry related to the sequential exposure to a halide and the metal alkyl. The 3-step “TMA+Plasma+TiCl4” sequence yields about the same growth rate as a full pair of oxides in a 4-step sequence whereby the substrate is exposed to plasma after each metal precursor (e.g., TMA+Plasma+TiCl₄+plasma), and still has much better barrier properties than either individual oxide alone. For example, the barrier properties yielded by the 3-step process “TMA+Plasma+TiCl4” are nearly as good as the properties resulting from the 4-step process.

It will be obvious to those having skill in the art that many changes may be made to the details of the above-described embodiments without departing from the underlying principles of the invention. The scope of the present invention should, therefore, be determined only by the following claims.

1. A method of depositing a barrier layer onto a substrate, comprising:
while maintaining the surface temperature of the substrate at less than 100° C., repeating the following sequence of steps multiple times until a film having a thickness of at least 2 nm is formed on the substrate:
(a) exposing the substrate to one of a halide or a metalorganic;
(b) after step (a), exposing the substrate to an oxygen plasma; and
(c) exposing the substrate to the other of the halide and the metalorganic.

2. The method of claim 1, in which the sequence of steps further comprises:
(d) after step (c), exposing the substrate to an oxygen plasma.

3. The method of claim 1, in a sub-sequence of steps (a) and (b) is repeated multiple times before performing step (c).

4. The method of claim 1, further comprising:
introducing gaseous halide in a first precursor zone;
introducing gaseous metalorganic in a second precursor zone spaced apart from the first precursor zone;
introducing an oxygen-containing gas into an isolation zone interposed between the first and second precursor zones so as to create a pressure in the isolation zone that is slightly higher than pressures in the first and second precursor zone;
imparting relative movement between the substrate and the precursor zones; and
energizing the oxygen-containing gas in the isolation zone in proximity to the substrate so as to generate the oxygen plasma.

5. The method of claim 4, wherein the substrate is transported back and forth between the first and second precursor zones multiple times, and each time through the isolation zone.

6. The method of claim 1, wherein the ratio of the number of times step (a) is performed to the number of times step (b) is performed is between 1:1 and 3:1, and in which step (a) comprises exposing the substrate to the halide.

7. The method of claim 1, wherein the step (b) includes exposing the substrate to the oxygen plasma for at least 0.25 second.

8. The method of claim 1, wherein the surface temperature of the substrate is maintained between 50° C. and 80° C. during the deposition of the barrier layer.

9. The method of claim 1, wherein the substrate is a flexible BOPP film.

10. The method of claim 1, wherein the halide is TiCl₄ and the metalorganic is TMA.

11. The method of claim 2, wherein the halide is TiCl₄ and the metalorganic is TMA.

12. The method of claim 4, wherein the halide is TiCl₄ and the metalorganic is TMA.

13. The method of claim 6, wherein the halide is TiCl₄ and the metalorganic is TMA.

14. The method of claim 7, wherein the halide is TiCl₄ and the metalorganic is TMA.

15. A barrier layer deposited onto a flexible polymer substrate, the barrier layer having an overall thickness of less than 8 nm and comprising an AlTiO mixture, the barrier layer having a water vapor transmission rate of less than 5×10⁻⁴ g/m²/day.

16. A barrier layer according to claim 15, wherein the overall thickness is less than 6 nm.

17. A barrier layer according to claim 15, in which a refractive index of the barrier layer is less than 2.0.

18. A barrier layer according to claim 15, wherein the AlTiO mixture within the barrier layer has no individual sublayer of alumina or titania greater than 1.5 nm thick.

19. A barrier layer according to claim 15, wherein the barrier layer has an alumina to titania mole ratio in the range of 1:1 to 1:3.

20. A barrier layer deposited onto a flexible polymer substrate, the barrier layer having an overall thickness of less than 10 nm and comprising an AlTiO mixture, the barrier layer having a water vapor transmission rate of less than 5×10⁻⁶ g/m²/day.

21. A barrier layer according to claim 20, wherein the overall thickness is less than 8 nm.

22. A barrier layer according to claim 20, in which a refractive index of the barrier layer is less than 2.0.

23. A barrier layer deposited onto a flexible polymer substrate, the barrier layer having an overall thickness of less than 4 nm and comprising an AlTiO mixture, the barrier layer having a water vapor transmission rate of less than 0.005 g/m²/day.
